(19) United States
(12) Patent Application Publication
(10) Pub. No.: US 2011/0085304 A1
(43) Pub. Date: Apr. 14, 2011

(54) Thermal management device comprising thermally conductive heat spreader with electrically isolated through-hole vias

(75) Inventors: Randy Bindrup, Trabucco Canyon, CA (US); Michael Miyake, Placentia, CA (US)

(73) Assignee: Irvine Sensors Corporation, Costa Mesa, CA (US)

(21) Appl. No.: 12/925,147

(22) Filed: Oct. 13, 2010

Related U.S. Application Data
(60) Provisional application No. 61/279,089, filed on Oct. 14, 2009.

(51) Int. Cl. H05K 7/20; F28F 7/00; B21D 53/02; H05K 13/00

(52) U.S. Cl. 361/718; 165/185; 29/890.03; 216/13

(57) ABSTRACT

A thermally conductive heat spreader is disclosed comprising one or more electrically isolated through-hole vias to provide, for instance, one or more thermal management layers having one or more electrically insulated and electrically conductive through-hole vias in a microelectronic module for the rerouting of one or more electrical signals to one or more layers in a stack of integrated circuit chip layers.

The method of the invention comprises disposing an electrically conductive member within an aperture in a heat spreader blank wherein the electrically conductive member is electrically insulated from the heat spreader blank by means of a dielectric layer to provide a vertical through-hole via for the vertical routing of an electrical signal through the heat spreader.

### STATEMENT REGARDING FEDERALLY SPONSORED RESEARCH AND DEVELOPMENT

This invention was made with Government support under Contract No. FA-8650-04-C-7120 awarded by United States Air Force.

The Government has certain rights in the invention.

### CROSS-REFERENCE TO RELATED APPLICATIONS

This application claims the benefit of U. S. Provisional Patent Application No. 61/279,089, filed on Oct. 14, 2009 entitled “Thermally Conductive Heat Spreader With Vertically Isolated Electrical Conductors,” pursuant to 35 USC 119, which application is incorporated fully herein by reference.

### DESCRIPTION

1. Field of the Invention

The invention relates generally to the field of thermal management in an electronic circuit.

More specifically, the invention relates to a thermally conductive heat spreader comprising one or more electrically insulated through-hole vias used in an electronic circuit or module for the rerouting of one or more electrical signals through the heat spreader such as to one or more layers in a stack of integrated circuit chip layers.

2. Background of the Invention

Stacked microelectronic modules comprised of layers containing integrated circuitry are desirable in that three-dimensional structures provide increased circuit density per unit area. The elements in a three-dimensional module are typically arranged in a stacked configuration and may comprise stacked integrated circuit die, stacked prepackaged integrated circuit packages, stacked modified prepackaged integrated circuits or stacked neo-layers such as disclosed in the various U.S. patents below.

The patents below disclose devices and methods wherein layers containing integrated circuit chips are stacked and electrically interconnected using any number of stacking techniques. For example, Irvine Sensors Corporation, assignee of the instant application, has developed several patented techniques for stacking and interconnecting multiple integrated circuits. Some of these techniques are disclosed in U.S. Pat. Nos. 4,525,921; 4,551,629; 4,646,128; 4,706,166; 5,104,820; 5,347,428; 5,432,729; 5,688,721; 5,953,588; 6,117,704; 6,560,109; 6,706,971; 6,717,061; 6,734,370; 6,806,559 and U.S. Pub. No. 2006/0087883.

Generally speaking, in a three-dimensional module, components containing integrated circuits are bonded together one on top of another so as to maintain a “footprint” approximately equivalent to that of the largest layer in the stack. The input/output connections of the various integrated circuit die in the layers are electrically rerouted the lateral surface of the module or to conductive area interconnects or electrically conductive vias defined at one or more predetermined locations in the stack.

A common method of electrically interconnecting the layers comprises electrically rerouting the input/output connections to the edges of the layers to define one or more access leads. Conductive T-connect structures for interconnecting one or more layers by means of connecting the one or more access leads are defined on the sides of the component stack. These input/output connections are electrically interconnected on the sides of the component stack using photolithographic and conductive plating processes to create T-connects using techniques such as those described in the patents identified above though which are vulnerable to environmental and handling damage.

Another method for interconnecting layers in a stack comprises the use of electrically conductive vias that are defined at predetermined locations in the stack and used to electrically interconnect one or more layers in a stack.

The increased circuit density of the above modules is desirable but the increased power dissipation of a stack of microelectronic circuits results in increased heat and related thermal management issues.

The instant invention addresses thermal management in a microelectronic module while maintaining the overall density and geometry of the stack by providing one or more electrically conductive vias for communication between layers.

### SUMMARY OF THE INVENTION

The device of the invention is a thermally conductive heat spreader comprising one or more electrically isolated through-hole vias to provide a thermal management layer for use in a microelectronic module. The heat spreader comprises one or more electrically insulated and electrically conductive through-hole vias for use in a microelectronic module for the rerouting of one or more electrical signals to one or more layers in a stack of integrated circuit chip layers.

The method of the invention generally comprises disposing an electrically conductive member within an aperture in a heat spreader blank wherein the electrically conductive member is electrically insulated from the heat spreader blank by means of a dielectric layer to provide a vertical through-hole via for the vertical routing of an electrical signal through the heat spreader blank.

While the claimed apparatus and method herein has or will be described for the sake of grammatical fluidity with functional explanations, it is to be understood that the claims, unless expressly formulated under 35 USC 112, are not to be construed as necessarily limited in any way by the construction of “means” or “steps” limitations, but are to be accorded the full scope of the meaning and equivalents of the definition provided by the claims under the judicial doctrine of equivalents, and, in the case where the claims are expressly formulated under 35 USC 112, are to be accorded full statutory equivalents under 35 USC 112.

### BRIEF DESCRIPTION OF THE DRAWINGS

FIG. 1 depicts a three-dimensional microelectronic module comprised of layers containing integrated circuit chips and a plurality of heat spreaders in thermal communication with a cold plate.

FIG. 2 is a cross-section of a portion of FIG. 1 showing detail of a conductive through-hole via of the invention.

FIGS. 3a and 3b, 4a and 4b, 5a and 5b, and 6a and 6b, depict steps in a preferred embodiment of a method for making the heat spreader of the invention.

FIGS. 7a-7g illustrate steps in an alternative preferred embodiment of a method for making the heat spreader of the invention.

FIGS. 8a-8g illustrates steps in a further alternative preferred embodiment of a method for making the heat spreader of the invention.

FIG. 9a shows a prior art electronic circuit using a heat sink element.

FIG. 9b illustrated a heat spreader of the invention incorporated into an electronic circuit comprised of a single integrated circuit chip.

The invention and its various embodiments can now be better understood by turning to the following detailed description of the preferred embodiments which are presented as illustrated examples of the invention defined in the claims. It is expressly understood that the invention as defined by the claims may be broader than the illustrated embodiments described below.

### DETAILED DESCRIPTION OF THE INVENTION

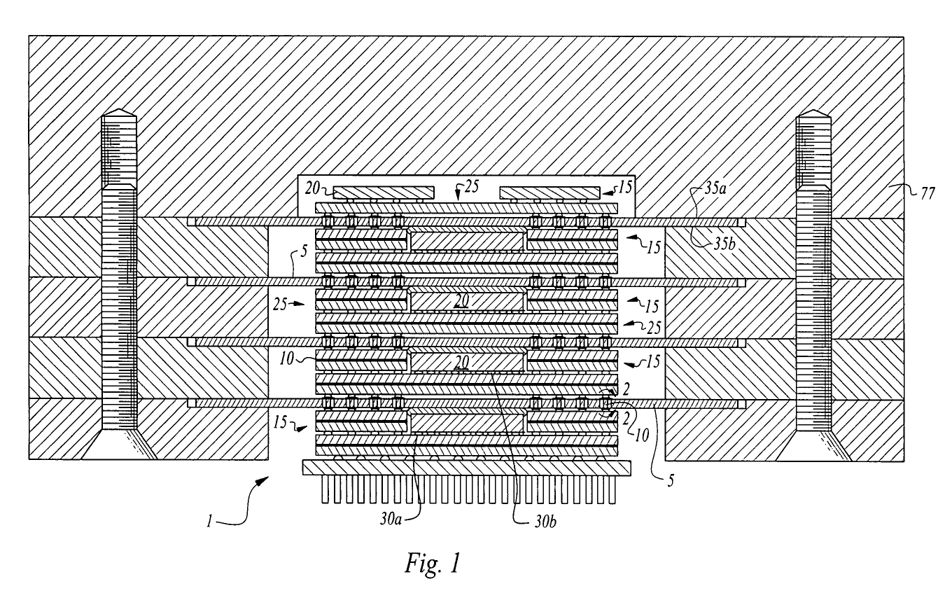

Turning now to the figures wherein like numerals depict like elements among the several views, FIG. 1 depicts a preferred embodiment of a three-dimensional electronic module 1 compromising a plurality of thermally conductive heat spreaders 5. Heat spreaders 5 each comprise one or more electrically isolated through-hole vias 10.

In FIG. 1, a cross-section of the exemplar electronic module 1, comprising five integrated circuit chip layers 15, is shown; each layer comprising one or more semiconductor integrated circuit chips or packages 20 (commonly referred to as “IC”s). Integrated circuit chips 20 may comprise one or more bare integrated circuit die, one or more prepackaged integrated circuits, one or more modified prepackaged integrated circuits or one or more neo-layers such as are disclosed in the various U.S. patents above.

Integrated circuit chips 20 are electrically connected to one or more reroute layers 25 comprised of one or more conductive traces each having one or more electrical bond pads for connection to an integrated circuit chip. Reroute layers 25 are preferably formed as a multilayer structure having multiple layers of conductive traces fabricated from FR-4, Kapton or the like, and are fabricated using known printed circuit board/photolithographic processes.

Reroute layers 25 function to reroute at least a first input/output electrical connection 30a to a second input/output electrical connection 30b of one or more integrated circuit chips 20 or to one or more predetermined locations in the stack (e.g., power, clock, reset, data, ground I/O of one or more integrated circuits in the stack).

In the case of bare integrated circuit die, the die may be electrically connected to the reroute substrate by means of flip chip bonding, wire bonding or thermo-compression processes.

Heat spreader 5 is preferably fabricated from a highly thermally conductive material such as copper, aluminum, brass or any material having suitable electrical and thermal conductivity and a suitable coefficient of thermal expansion.

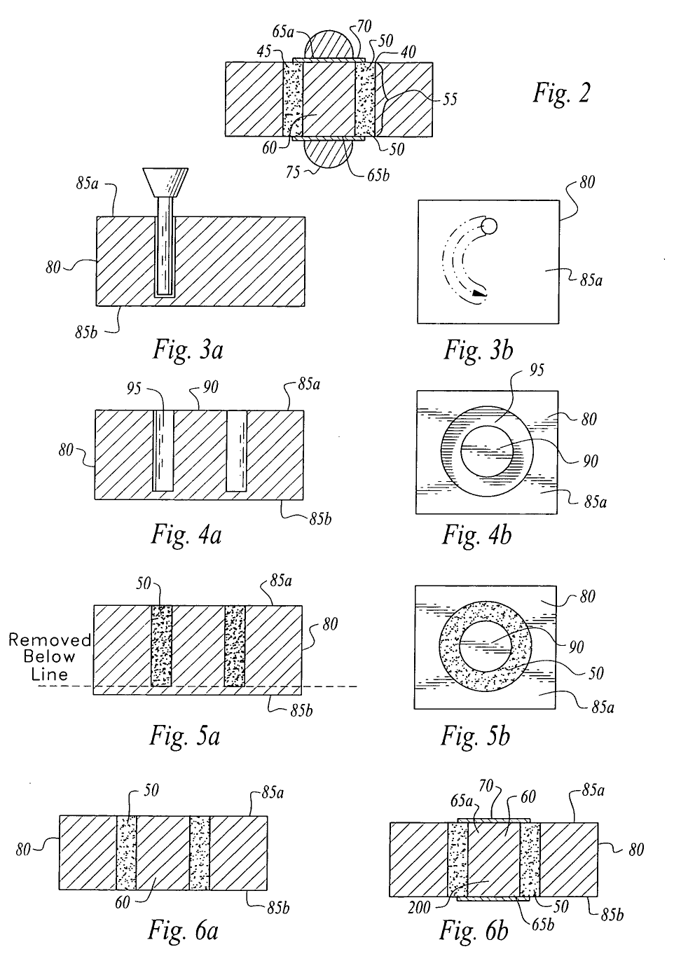

As is depicted in FIGS. 1, and 2, heat spreader 5 comprises one or more vias 10 for the routing of one or more electrical signals vertically between one or more layers 15, such as by reroute layers 25.

As better seen in FIG. 2, heat-spreader 5 comprises a first major surface 35a and a second major surface 35b and has one or more apertures 40 defined through heat spreader 5 and having an interior surface 45. Interior surface 45 has a dielectric layer 50 disposed thereon to define an insulated through-hole via 55.

Dielectric layer 50 comprises an electrical insulating layer having suitable dielectric and coefficient of thermal expansion properties to substantially match the material from which heat spreader 5 is fabricated. In a preferred embodiment, a potting/encapsulant material such as HYSOL 4450 available from HENKLE LOCTITE CORPORATION, comprises dielectric layer 50.

Insulated through-hole via 55 further comprises an electrically conductive member 60 substantially centrally disposed along the vertical axis of via 55 and having a first terminal end 65b electrically accessible on the first major surface 35a, and a second terminal end 65b electrically accessible on the second major surface 35b.

An electrically conductive pad 70 and solder ball 75 are preferably defined on each of the first and second terminal ends for subsequent connection to first and second electrical connections 30a and 30b.

In the microelectronic module of FIG. 1, a first electrical connection of a first integrated circuit chip in a first integrated circuit chip layer and a second electrical connection of a second integrated circuit chip in a second integrated circuit chip layer can be connected so as to be in electrical communication by means of the electrically conductive member defined in and through heat spreader 5.

The use of area vias (also known as area interconnects), such as via 10, in a three-dimensional microelectronic module, provides significant advantages over the use of a conductive wire or trace formed on a lateral surface of a component stack. For example, the use of vias both hides and protects the interconnections between component layers within the stack.

In one aspect of the invention, one or more portions of heat spreader 5 are in thermal communication with heat extraction means 77 such as a cold plate, radiator, external heat sink or heat radiating fins for the extraction of heat generated by the integrated circuit chips that has been transferred to the heat spreader.

In a further aspect of the invention, a cooling medium is passed over at least a portion of the first or second major surfaces of heat spreader 5 or heat extraction means 77, such a liquid coolant (e.g., water, ethylene glycol) or an air flow for the efficient radiation of heat from the heat spreader 5 to an external location.

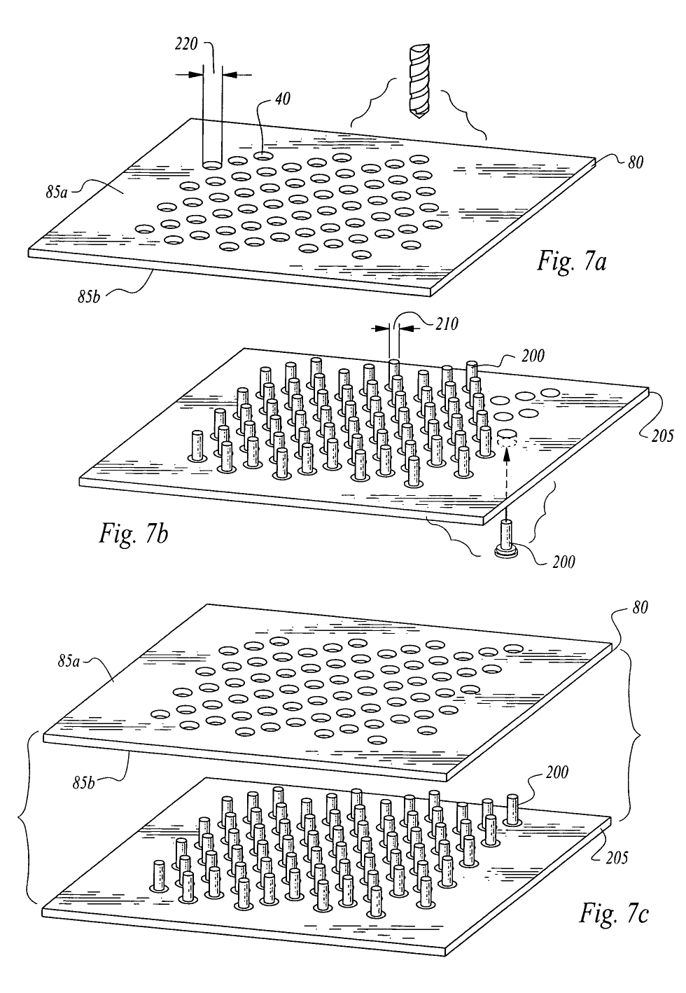

A first preferred embodiment of a method for making the heat spreader 5 of the invention is depicted in FIGS. 3a and 3b, 4a and 4b, 5a and 5b and, 6a and 6b.

The method comprises the steps of providing a heat spreader blank 80 having a first major heat spreader blank surface 85a, and a second major heat spreader blank surface 85b. In a preferred embodiment, heat spreader blank 80 is a blank copper layer, but as indicated above, may be aluminum, brass or any material of suitable electrical and thermal property.

As seen in FIGS. 3a and 3b and 4a and 4b, a portion of first major heat spreader blank surface 85a of heat spreader blank 80 is removed to a predetermined depth to define a column 90 and a perimeter volume 95.

Electrical discharge machining (EDM) is a preferred method of defining column 90 and perimeter volume 95 because of the ability to precisely control the depth and width of the volume of the material being removed. Alternative embodiments of the method for material removal from the heat spreader blank 80 comprise the use of chemical etching processes or laser ablation means.

As depicted in FIGS. 5a and 5b, the perimeter volume 95 is filled with a dielectric material such as HYSOL 4450 to define dielectric layer 50.

As depicted in FIGS. 5a and 6a, a predetermined portion of second major heat spreader blank surface 85b of heat spreader blank 80 is removed to expose dielectric layer 50 and define an electrically conductive member 60 that provides an electrical conductor for an electrical signal to be vertically routed through heat spreader blank 80 and that is electrically insulated therefrom.

Processes for removing the predetermined portion of second major heat spreader blank surface 85b may comprise for instance, grinding, etching, lapping or other precision material removal processes as are known in the art of semiconductor and printed circuit board fabrication.

As depicted in FIG. 6b, an electrically conductive bond pad 70 is desirably provided on the now-exposed terminal ends of electrically conductive member 60 for improved electrical connection and solderability.

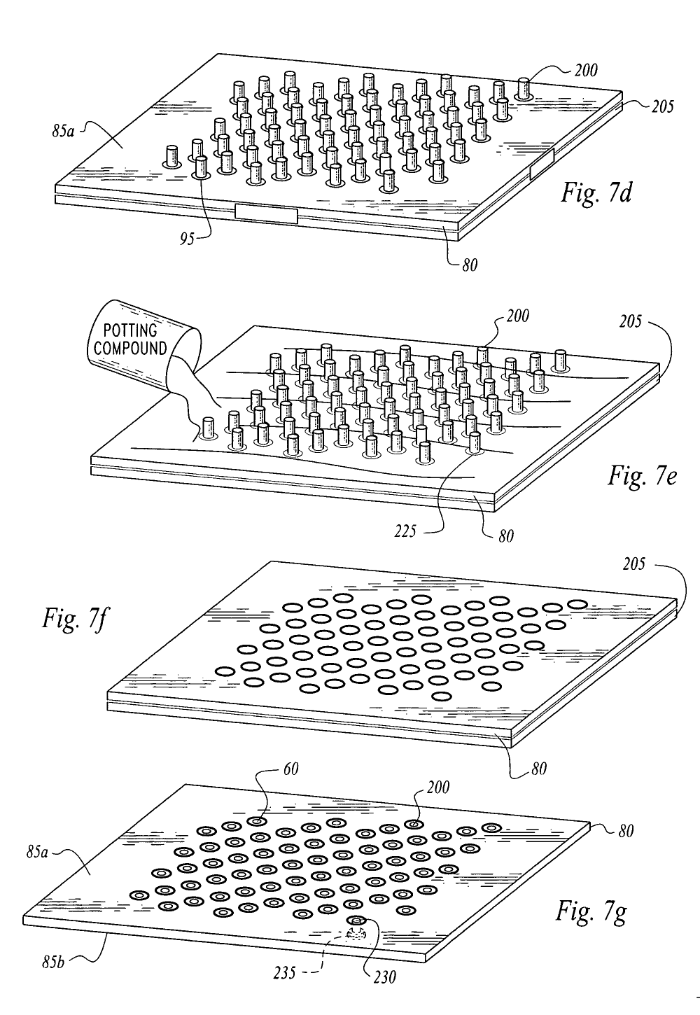

Turning now to FIGS. 7a-7g, an alternative preferred embodiment of the method for making heat spreader 5 of the invention comprises the steps defining a separately fabricated electrically conductive member, here an electrically conductive post, wire or other structure 200 having a predetermined outer diameter 210, on a sacrificial substrate 205.

A heat spreader blank 80 is provided, having a predetermined thermal conductivity and having a first major heat spreader blank surface 85a and a second major heat spreader blank surface 85b.

An aperture 40, having an inner diameter 220 greater than the outer diameter 210 of the electrically conductive post 200, is defined through heat spreader blank 80.

Methods of defining aperture 40 include mechanical drilling, EDM, chemical etching, laser ablation and the like as are known in the machining arts.

As depicted in FIGS. 7c and 7d, substrate 205 is then bonded to heat spreader blank 80 whereby electrically conductive post 200 is substantially centered within and along the axis of aperture 40 and defines a perimeter volume 95.

As depicted in FIG. 7e, perimeter volume 95 is then filled with a dielectric material, preferably HYSOL 4450, and the material allowed to cure to define an insulated perimeter volume 225.

Sacrificial substrate 205 is then removed by grinding, etching or an equivalent process to expose a portion of electrically conductive post 200 to define an electrically conductive member 60. The first and second major heat spreader blank surfaces 85a and 85b are processed such as by lapping or grinding to expose first terminal end 230 and second terminal end 235 of electrically conductive member 60 to define a heat spreader 5 of the invention, comprising one or more vertical electrically conductive members 60.

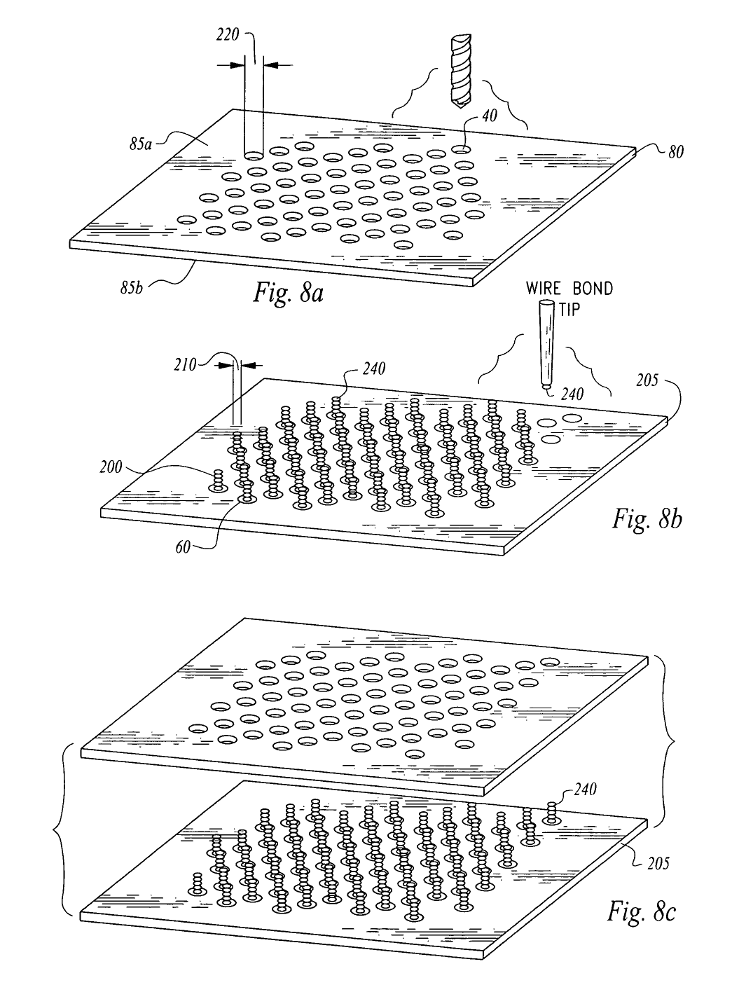

As depicted in FIGS. 8a-8g, in an alternative embodiment of the above method, a wire bond “stud bump” or a plurality of stacked wire bond stud bumps 240 are defined on sacrificial substrate 205 to define an electrically conductive post 200 having a predetermined outer diameter 210, thus defining electrically conductive member 60.

A heat spreader blank 80 is provided, having a predetermined thermal conductivity and having a first major heat spreader blank surface 85a and a second major heat spreader blank surface 85b.

An aperture 40 is defined through the heat spreader blank 80, having an inner diameter 220 greater than the outer diameter 210 of electrically conductive post 200. Methods of defining aperture 40 may include drilling, EDM, chemical etching, laser ablation and the like as are well known in the machining arts.

As depicted in FIGS. 8c and 8d, substrate 205 is bonded to heat spreader blank 80 whereby electrically conductive post 200 that is defined by the one or more wire ball stud bumps 240 is substantially centered within and along the central axis of aperture 40 and defines a perimeter volume 225.

As depicted in FIG. 8e, perimeter volume is filled with a dielectric material, preferably HYSOL 4450, and the material allowed to cure to define an insulated perimeter volume 225.

Stud bump columns of 5 to 6 bumps high having a diameter of about five mils have been successfully fabricated using conventional wire bond equipment such as the ESEC 3088 Wire Bond Machine.

As better seen in FIGS. 8f and 8g, sacrificial substrate 205 is then removed by grinding, etching or the like to expose a portion of the electrically conductive post 200 defined by the one or more wire ball stud bumps.

First and second major heat spreader blank surfaces 85a and 85b are processed such as by lapping or grinding to expose the first terminal end 230 and second terminal end 235 of conductive member 60 (i.e., the uppermost and lowermost surface of the one or more wire bond stud bumps) to provide heat spreader 5 of the invention comprising one or more vertical electrically conductive members.

A preferred embodiment of the heat spreader 5 of the invention comprises apertures of about 20 mils in diameter, having an electrically conductive member 60 substantially centrally disposed therein and having a diameter of about 10 mils; which geometries are well-suited for applications in microelectronic modules and devices.

It is expressly noted that use of heat spreader 5 of the invention is not limited to multilayer modules but may be beneficially incorporated into any electronic circuit where enhanced thermal management is desired.

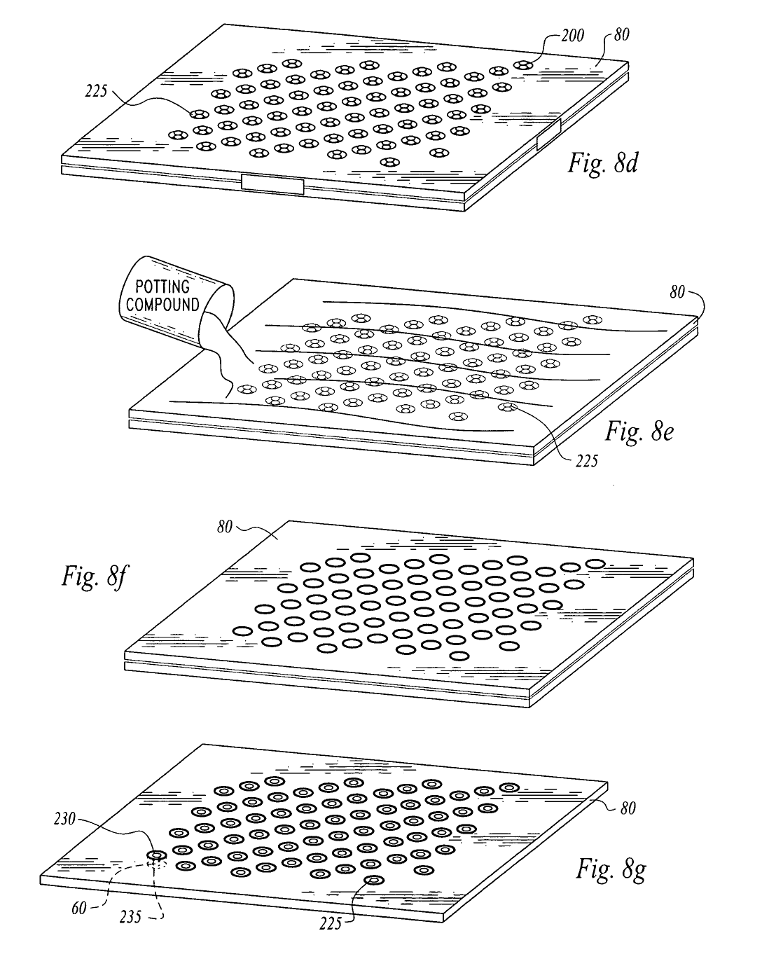

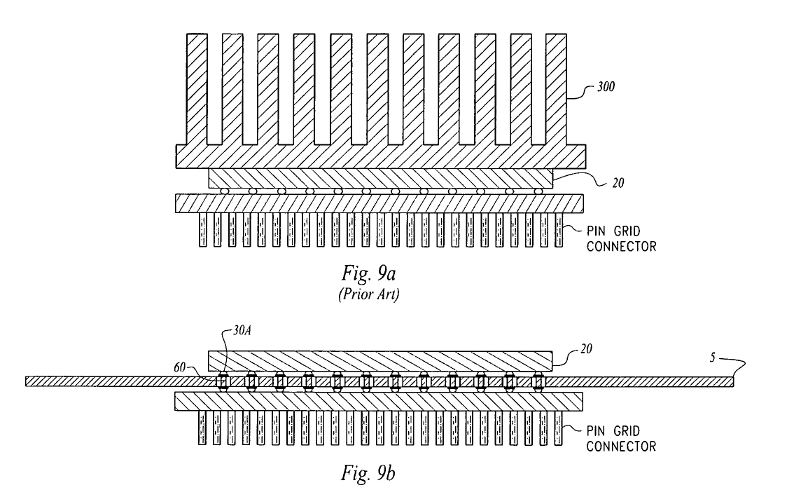

For instance, FIG. 9a shows a prior art thermal management heat sink 300 used to dissipate heat generated by an integrated circuit chip 20. The use of a heat sink undesirably increases the vertical height of the combined circuit elements of FIG. 9a.

As depicted in FIG. 9b, heat spreader 5 is disposed between integrated circuit 20 and having a first electrical connection 30a in electrical connection with electrically conductive member 60. Electrically conductive member 60 is connected to an external circuit (shown here as a pin grid connector element) whereby the integrated circuit chip I/O signals are routed to external circuitry thru electrically conductive member 60 in heat spreader 5 in a single integrated circuit embodiment.

This orientation is particularly effective for device thermal management in that heat generated by an integrated circuit chip tends to follow the path of least thermal resistance which, in this case, are the thermally conductive I/O structures in the integrated circuit chip disposed in close proximity to heat spreader 5.

Many alterations and modifications may be made by those having ordinary skill in the art without departing from the spirit and scope of the invention. Therefore, it must be understood that the illustrated embodiment has been set forth only for the purposes of example and that it should not be taken as limiting the invention as defined by the following claims. For example, notwithstanding the fact that the elements of a claim are set forth below are in a certain combination, it must be expressly understood that the invention includes other combinations of fewer, more or different elements, which are disclosed above even when not initially claimed in such combinations.

The words used in this specification to describe the invention and its various embodiments are to be understood not only in the sense of their commonly defined meanings, but to include by special definition in this specification structure, material or acts beyond the scope of the commonly defined meanings. Thus, if an element can be understood in the context of this specification as including more than one meaning, then its use in a claim must be understood as being generic to all possible meanings supported by the specification and by the word itself.

The definitions of the words or elements of the following claims are, therefore, defined in this specification to include not only the combination of elements which are literally set forth, but all equivalent structure, material or acts for performing substantially the same function in substantially the same way to obtain substantially the same result. In this sense, it is therefore contemplated that an equivalent substitution of two or more elements may be made for any one of the elements in the claims below or that a single element may be substituted for two or more elements in a claim. Although elements may be described above as acting in certain combinations and even initially claimed as such, it is to be expressly understood that one or more elements from a claimed combination can in some cases be excised from the combination and that the claimed combination may be directed to a subcombination or variation of a subcombination.

Insubstantial changes from the claimed subject matter as viewed by a person with ordinary skill in the art, now known or later devised, are expressly contemplated as being equivalently within the scope of the claims. Therefore, obvious substitutions now or later known to one with ordinary skill in the art are defined to be within the scope of the defined elements. The claims are thus to be understood to include what is specifically illustrated and described above, what is conceptually equivalent, what can be obviously substituted and also what essentially incorporates the essential idea of the invention.

We claim:

1. A thermal management device having an electrically conductive member comprising:
a heat spreader having a first major surface and a second major surface,
an aperture defined through the heat spreader and having an interior surface,
a dielectric layer disposed on the interior surface of the aperture to define an insulated through-hole via, and,
an electrically conductive member disposed in the via and having a first terminal end electrically accessible on the first major surface and a second terminal end electrically accessible on the second major surface.

2. The device of claim 1 further comprising heat-extraction means for extracting heat from at least a portion of the heat spreader.

3. The device of claim 1 further comprising a first integrated circuit chip having a first electrical connection in electrical communication with the electrically conductive member.

4. The device of claim 2 wherein the heat extraction-means comprises a cold-plate element.

5. The device of claim 2 wherein the heat-extraction means comprises passing a cooling medium over at least a portion of the first or second major surface of the heat spreader.

6. An electronic module comprising:
a stack of integrated circuit chips comprising a first integrated circuit chip layer having a first electrical connection and a second integrated circuit chip layer having a second electrical connection,
a heat spreader disposed between the first integrated circuit chip layer and the second integrated chip layer and having a first major surface and a second major surface,
an aperture defined through the heat spreader having an interior surface,
a dielectric layer disposed on the interior surface of the aperture to define an insulated through-hole via,
an electrically conductive member disposed in the via and having a first terminal end electrically accessible on the first major surface and a second terminal end electrically accessible on the second major surface, and,
the first electrical connection and the second electrical connection in electrical communication by means of the electrically conductive member.

7. A method for making a heat spreader having a vertical electrically conductive member comprising the steps of:
providing a heat spreader blank having a first major heat spreader blank surface and a second major heat spreader blank surface,
removing a portion of the heat spreader blank on the first major heat spreader blank surface to a predetermined depth to define a column and a perimeter volume,
filling the perimeter volume with a dielectric material, and,
removing a predetermined portion of the second major heat spreader surface of the heat spreader blank to define an electrically conductive member that is electrically insulated from the heat spreader blank.

8. The method of claim 7 wherein the column and perimeter volume are defined by an electrical discharge machining process.

9. The method of claim 7 wherein the column and perimeter volume are defined by a chemical etching process.

10. A method for making a heat spreader having a vertical electrically conductive member comprising the steps of:
defining an electrically conductive member having an outer diameter on a substrate,
providing a heat spreader blank,
defining an aperture having an inner diameter greater than the outer diameter of the electrically conductive member in the heat spreader blank,
bonding the substrate to the heat spreader blank whereby the electrically conductive member is substantially centered within the aperture and defines a perimeter volume,
filling the perimeter volume with a dielectric,
removing the substrate to expose a portion of the electrically conductive member.

11. The method of claim 10 wherein the electrically conductive member is an electrically conductive post.

12. The method of claim 10 wherein the electrically conductive member comprises a stud bump.

13. The method of claim 10 wherein the electrically conductive member comprises a plurality of stacked stud bumps.
